(19) United States
(12) Patent Application Publication
(10) Pub. No.: US 2014/0035633 A1
(43) Pub. Date: Feb. 6, 2014

(54) AUTONOMOUS INITIALIZATION METHOD OF FACING PORT OF SEMICONDUCTOR INTEGRATED CIRCUIT AND SEMICONDUCTOR INTEGRATED CIRCUIT

(71) Applicant: Fujitsu Limited, Kawasaki-shi (JP)

(72) Inventors: Junji ICHIMIYA, Yokohama (JP); TAKESHI OWAKI, Kawasaki (JP); Daisuke ITO, Kawasaki (JP); Atsushi MOROSAWA, Kawasaki (JP); NORIHIKO FUKUZUMI, Ashigarashimo (JP)

(73) Assignee: Fujitsu Limited, Kawasaki-shi (JP)

(21) Appl. No.: 14/047,714

(22) Filed: Oct. 7, 2013

Related U.S. Application Data
(63) Continuation of application No. PCT/JP2011/059452, filed on Apr. 15, 2011.

(51) Int. Cl. H03L 7/00

(52) U.S. Cl. CPC H03L 7/00
USPC 327/142

(57) ABSTRACT

On a transmission path connecting a first semiconductor integrated circuit that is started by a system management apparatus and a second semiconductor integrated circuit that is not started by the system management apparatus, when connection of the first semiconductor integrated circuit to the second semiconductor integrated circuit is detected, after being turned to a first signal state for detecting a valid lane, each lane on the transmission path is turned to a second signal state corresponding to each bit of initial setting code. In the second semiconductor integrated circuit, the first and second signal states are detected for each lane of the transmission path. Based on the detected signal state, after detecting the first signal state, the second signal state is detected and each bit value of the initial setting code is decoded. Based on the decoded initial setting code, an initialization process is executed.

### CROSS-REFERENCE TO RELATED APPLICATIONS

This application is a continuation application of International Application PCT/JP2011/59452 filed on Apr. 15, 2011 and designated the U.S., the entire contents of which are incorporated herein by reference.

### FIELD

The embodiments discussed herein are related to an initialization method and apparatus of a physical layer performing electrical communication in a system consisting of a plurality of semiconductor integrated circuits.

### BACKGROUND

There has been an ever-increasing demand for improving processing ability. In response to this demand, the performance of semiconductor integrated circuits such as a CPU (Central Processing Unit) for which the main purpose is arithmetic processing and the like is becoming higher and higher. Moreover, in computer systems in recent years, to improve their processing ability, there have been more systems that constitute a large-scale system by a number of semiconductor devices being connected. Thus, for a connected CPU, the number of connections increases more and more with performance improvements in the CPU itself. Its usage is not only at a place such as research facilities conducting special arithmetic processing but it is also used in places such as companies. According to the large-scale computer system demand, the demand for a coupling technique of semiconductor integrated circuits such as the CPU is increasing more than ever.

In order for a plurality of semiconductor integrated circuits to operate in a synchronous manner, it is necessary to make it possible for the semiconductor integrated circuits to start up in synchronization with each other.

As a technique to synchronize semiconductor integrated circuits, a prior art has been known in which a system management device is connected via a system interface to each semiconductor integrated circuit, and the system management devices start the semiconductor integrated circuits connected to each of them in a synchronous manner with each other.

In addition, a prior art is also known in which, after initial setting of a semiconductor integrated circuit, a data path connecting semiconductor integrated circuits with each other is put into a state in which it is able to perform data transfer, and the semiconductor integrated circuits are started in a synchronous manner with each other using the data path.
Patent document 1: Japanese National Publication of International Patent Application No. 2007-513436
Patent document 2 Japanese National Publication of International Patent Application No. 2008-544378
Patent Document 3: Japanese Laid-open Patent Publication No. 8-237106

### SUMMARY

According to an aspect of the invention, on a transmission path connecting a first semiconductor integrated circuit (LSI 11) that is started by a system management apparatus and a second semiconductor integrated circuit (LSI 12) that is not started from the system management apparatus, when connection of the first semiconductor integrated circuit to the second semiconductor integrated circuit is detected, after being turned to a first signal state for detecting a valid lane, each lane (a4) on the transmission path is turned to a second signal state corresponding to each bit of initial setting code, and in the second semiconductor integrated circuit, a signal state is detected for each lane of the transmission path, and in the second semiconductor integrated circuit, for each lane of the transmission path, based on the detected signal state, when the second signal state is detected after detecting the first signal state, each bit value of the initial setting code is decoded, and based on the decoded initial setting code, the first semiconductor integrated circuit and the second semiconductor integrated circuit execute an initialization process of a facing port to which the transmission path is connected.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a generally-conceivable system with a plurality of LSIs (part 1).

FIG. 2 is a diagram illustrating a generally-conceivable system with a plurality of LSIs (part 2).

FIG. 3 is a diagram illustrating a generally-conceivable system with a plurality of LSIs (part 3).

FIG. 4 is a diagram illustrating a generally-conceivable system with a plurality of LSIs (part 4).

FIG. 5 is a diagram illustrating a system configuration example according to the first embodiment.

FIG. 6 is a diagram illustrating a configuration example of a system with a plurality of LSIs according to the second embodiment.

FIG. 7 is a diagram illustrating a facing lane configuration example according to the second embodiment.

FIG. 8 is a diagram illustrating a flowchart of a setting process of a physical layer initial setting value according to the second embodiment.

FIG. 9 is an explanatory diagram of an initial setting code communication operation according to the second embodiment.

FIG. 10 is a diagram illustrating an example of an initial setting code transmission lane according to the second embodiment.

FIG. 11 is a diagram illustrating an example of an initial setting code transmission prior notice pattern.

FIG. 12 is a diagram illustrating an example of a setting content of an initial setting code according to the second embodiment.

FIG. 13 is a diagram illustrating a facing lane configuration example according to the third embodiment.

FIG. 14 is an explanatory diagram of an initial setting code communication operation according to the third embodiment.

FIG. 15 is a diagram illustrating a configuration example of a receiver detector.

FIG. 16 is a diagram illustrating an operation waveform example at a level detector.

FIG. 17 is a diagram illustrating a flowchart of another embodiment of a setting process of a physical layer initial setting value.

### DESCRIPTION OF EMBODIMENTS

In the prior arts, there is a problem in which a system interface is needed for each semiconductor integrated circuit, expanding the circuit scale. In particular, with the growth in density of integration of the integrated semiconductor device in recent years, there has been an increasing trend wherein the die size of the LSI is determined by the number of interfaces of the LSI rather than the number of semiconductor devices of the LSI. Since the number of interfaces of the LSI has been on the increase with the higher performance of the LSI, there has been a challenge to reduce the number of interfaces of the LSI as much as possible.

Meanwhile, there has been a problem wherein, in order to start semiconductor integrated circuits in a synchronous manner with each other using a data path, a complicated procedure to enable data transfer on the data path is required, which delays the startup time.

Preferred embodiments of the present invention will be explained with reference to accompanying drawings.

In the explanation below, first, a generally-conceivable initialization method of a physical layer of a semiconductor integrated circuit is explained, and after clarifying its problems, the present embodiment is explained.

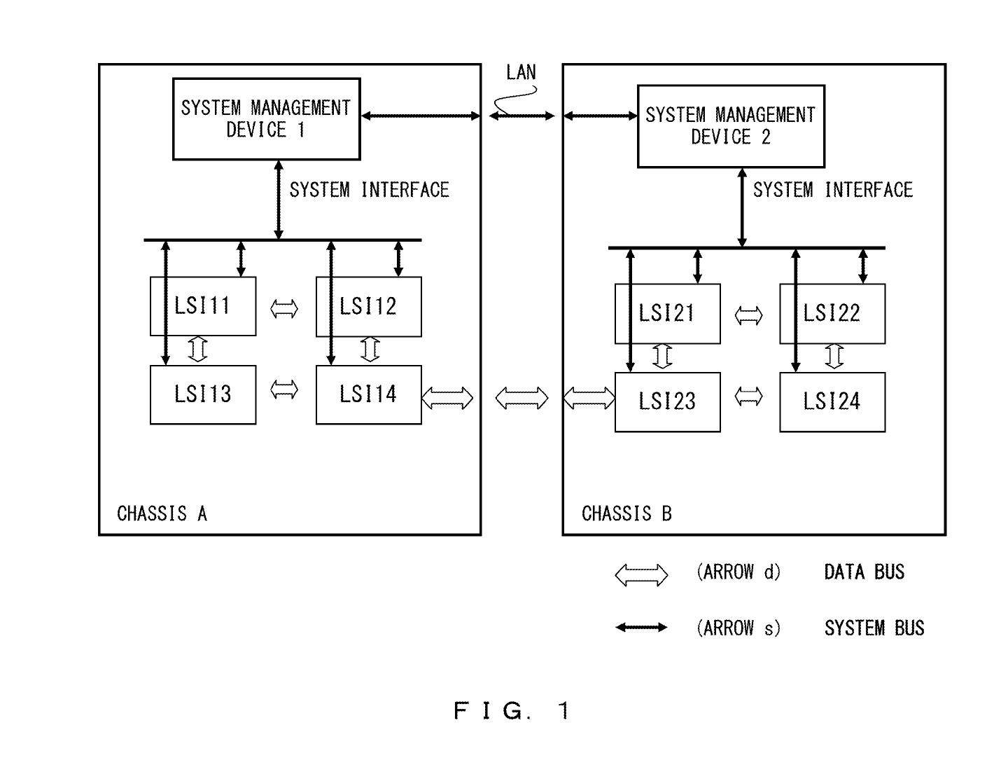

FIG. 1 illustrates a connection outline of a generally-conceivable system with a plurality of LSIs (part 1). The example illustrates an example in which computer chassis A and B are connected.

In this example, in the chassis A and B, through an inter-chassis transmission path, an LSI 14 and an LSI 23, which are each large-scale semiconductor integrated circuits, are connected respectively. In addition, a system management device 1 and a system management device 2 are connected between the chassis by a LAN cable.

In the computer chassis A and B respectively, four large-scale semiconductor integrated apparatuses are provided (hereinafter, simply referred to as a “semiconductor integrated circuit”). The semiconductor integrated circuit apparatus is for example a CPU (Central Processing Unit), a device such as an NC (Node Controller) that controls each CPU (node), or a PCI (Peripheral Components Interconnect bus) switch. An arrow d in FIG. 1 is a data bus line to exchange data between the respective LSIs, and an arrow s is a communication signal line used for register setting and the like from the system management device to each LSI. (This signal line is often two signal lines in general. In this specification, for convenience of explanation, this signal line is explained as one line.)

In such a system, the system management device 1 needs to perform the setting for the LSI 11-LSI 14, and the system management device 2 needs to perform the setting for the LSI 21-LSI 24. That is, in that case, the respective system management devices need to communicate with each other, and start the LSI 11-LSI 14 and the LSI 21-LSI 24 in a synchronous manner. In this case, the user is unable to perform the setting and start the LSI 21-LSI 24 mounted on the chassis B from the system management device 1.

That is, the user needs to access both the chassis A and the chassis B. Meanwhile, the system management device sets the operation speed of the data bus connecting the LSIs with each other, and sets the value of various setting registers.

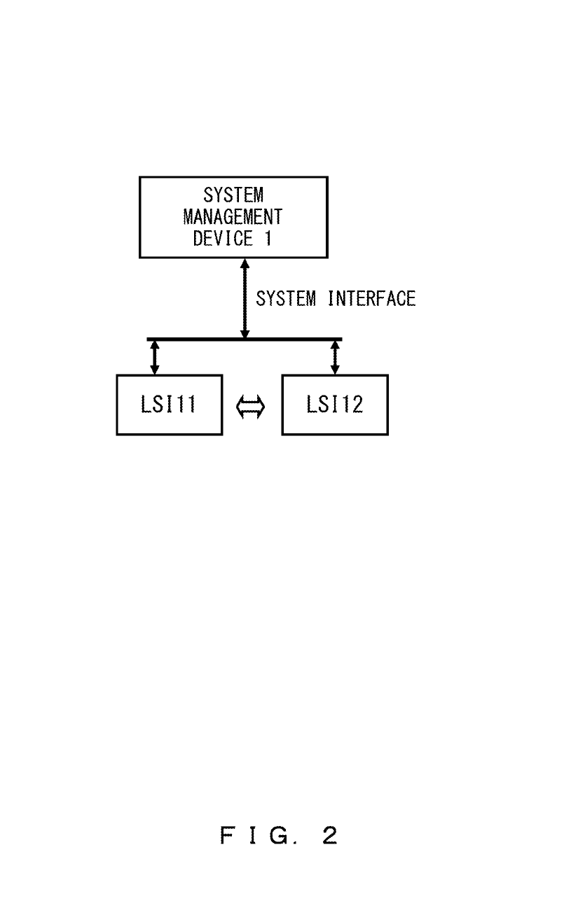

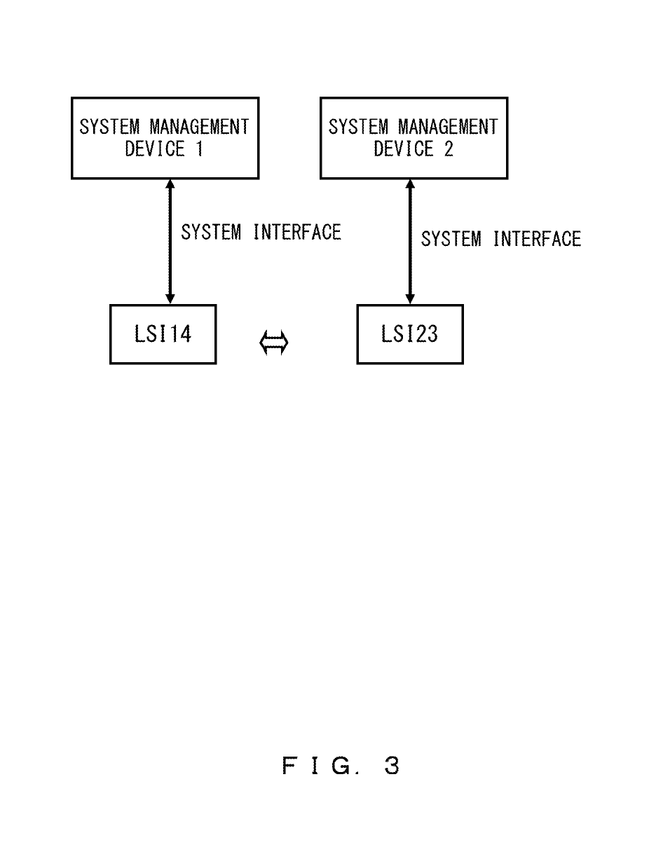

Further, in FIG. 2 and FIG. 3, in order to illustrate the connection of the generally-conceivable system with a plurality of LSIs illustrated in FIG. 1 in an easily understandable manner, a partial extraction of the connection between LSIs is illustrated. FIG. 2 illustrates a configuration to perform initialization of LSIs in the same chassis, and FIG. 3 illustrates a configuration to perform initialization of LSIs between different chassis, in a simplified manner.

In FIG. 2, the system management device 1 performs the setting of initialization of the LSI 11 and the LSI 12. In FIG. 3, the system management device 1 performs the setting of the LSI 14, and the system management device 2 performs the setting of the LSI 23. Thus, since the system management device needs to access each device, a system interface is required for each LSI. Or, due to the crossover between the respective chassis, a separate system management device is required for each LSI.

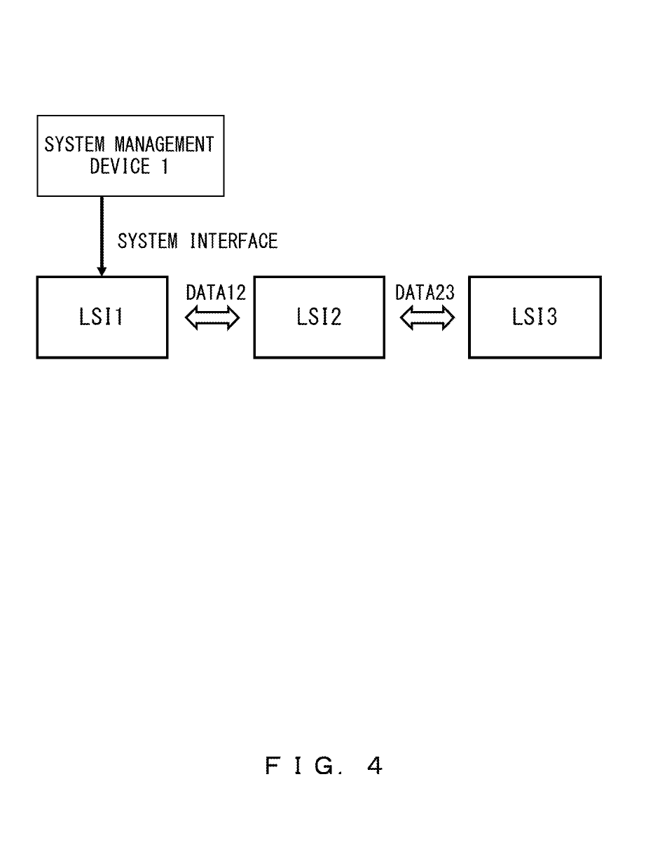

FIG. 4 illustrates a generally-conceivable system with a plurality of LSIs different from FIG. 2 and FIG. 3. Unlike FIG. 2 and FIG. 3, each LSI does not have any special system interface. Each LSI autonomously opens a data path (DATA 12 or DATA 23 in FIG. 4) first, so as to be able to perform data transmitting/receiving, that is, moves to a state to be able to perform data transfer. After that, using the data path, it is also possible to perform setting of a facing LSI using the protocol of the data bus. However, in such as case, a complicated operation is required to be able to transfer normal data, and the startup operation takes a lot of time.

As described above, in the generally-conceivable methods, a separate system management device is required for each LSI, or, a complicated initialization operation is required for the setting of facing LSIs.

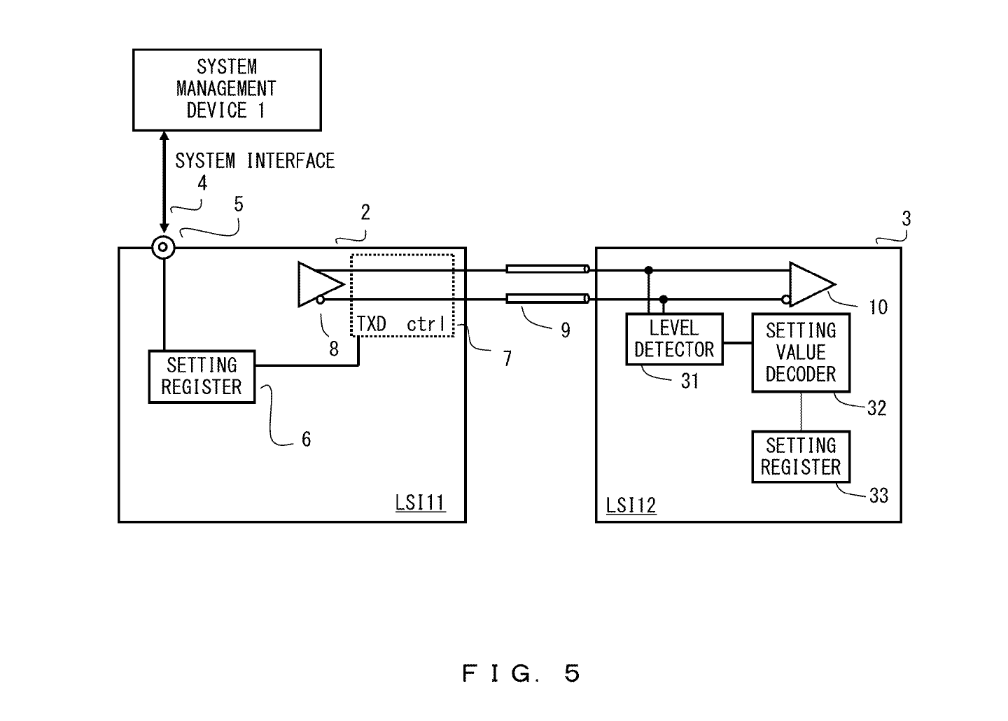

FIG. 5 illustrates a system configuration example according to the first embodiment to solve the problems in the generally-conceivable methods described above.

As illustrated in FIG. 5, the LSI 11 and the LSI 12, which are semiconductor integrated circuits, perform initialization of the physical layer by communicating the minimum required setting for initialization of the facing LSIs as an initial setting code, using a data bus to exchange normal data in the operating state.

The first embodiment is a configuration example of a computing system including a system management device 1, a semiconductor integrated circuit 2 (LSI 11), and a semiconductor integrated circuit 3 (LSI 12). The system management device 1 directly accesses a setting register 6 of the LSI 11 via a terminal 5 of the chip of the LSI 11, through a system interface 4. The LSI 11 transmits an initial setting value to the LSI 12 via a transmission path 9, which is a data bus to exchange normal data in the operating state, by switching the transmission data to the time of initialization by a transmission data lane control unit (TXD ctrl) 7. Meanwhile, after detecting the signal level of the transmission path 9 by a level detector 31, the LSI 12 decodes the minimum required initial setting value received via the transmission path 9 by a setting value decoder 32, and sets the values in its own setting value register 33.

In the first embodiment configured as described above, first, for the LSI 11, which is the first semiconductor integrated circuit 2, the initial setting value is set in the setting register 6 in the LSI 11 from the system management device 1, using the system interface 4 that is the same as conventional ones.

Next, for the LSI 12, which is the second semiconductor integrated circuit 3, the transmission data lane control unit 7 in the LSI 11 performs a communication operation as described below using a transmission path 9, which is a data bus to exchange normal data in the operating state. First, the transmission data lane control unit 7 is equipped with a receiver detector for detecting a facing lane. The detector is configured to be able to detect whether or not a facing semiconductor integrated circuit exists from the state of the lane. Next, in the respective lanes of the transmission path 9, a valid lane is determined. Then, the signal state of each lane of the transmission path is turned to a first signal state having a prescribed pattern, in which a logic level “0” and a logic level “1” change in an alternate manner at short first time intervals. Accordingly, the lane that is able to transmit the logic level “0” and the logic level “1” correctly is the valid lane. After the first signal state, the transmission data lane control unit 7 turns the signal state of each lane of the transmission path 9 into a second signal state having second time intervals that are sufficiently longer than the first time intervals, and each lane becomes the logic level “0” or “1” corresponding to each bit value “0” or “1” of the initial setting code. Alternatively, after the first signal state, the transmission data lane control unit 7 turns the signal level state of each lane of the transmission path 9 into a second state in which each lane enters the state having the prescribed pattern described above or the fixed state of the logic level, according to each bit value “0” or “1” of the initial setting code. By the second signal state, the port clock of the LSI 11 is communicated to the LSI 12 facing the LSI 11.

In the facing LSI 12, for each lane of the transmission path 9, each level detector 31 detects the signal level of each lane. Then, based on the detected signal level, the setting value decoder 32 detects the first signal state, which is the state of the prescribed pattern described above, and after the valid lane is decided, the subsequent second signal state corresponding to each bit value of the initial setting code is detected. By performing the detection operation for each lane, the setting value decoder 32 decodes the bit string of the initial setting code, and sets it in the setting register 33 in the LSI 12. Accordingly, the port clock of the LSI 12 becomes the same as the port clock of the LSI 11. Accordingly, the initial setting of the physical layer of the LSI 11 and the LSI 12 is performed.

As described above, in the first embodiment, even in the state in which the operating frequencies of the LSI 11 and the LSI 12 have not yet been synchronized using the transmission path 9, which is the data bus to exchange normal data in the operating state, communication between the LSI 11 and the LSI 12 may be performed, and the initial setting code may be communicated. By making the initial setting code correspond to the frequency value of the PLL (Phased Locked Loop) circuit for the port for example so as to adjust the operating frequencies of the LSI 11 and the LSI 12, it becomes possible to synchronize the operating frequencies between facing LSIs by communication of the initial setting code. Then, after synchronizing the operating frequencies, by communicating the normal packet command using the synchronized transmission path 9, it becomes possible to set other setting values for physical layer initialization from the LSI 11 to the facing LSI 12.

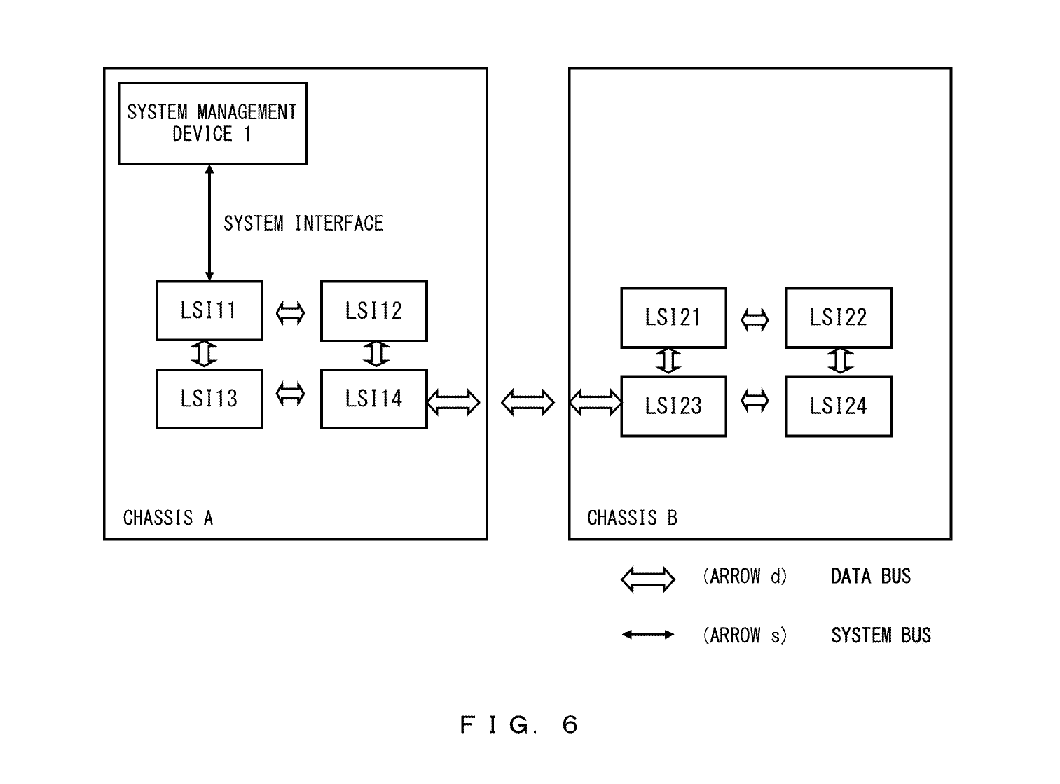

FIG. 6 is a diagram illustrating a configuration example of a system with a plurality of LSIs of the second embodiment. The second embodiment is a diagram illustrating the LSI 11 and the LSI 12 of the first embodiment, but more close to the system level. The second embodiment corresponds to the generally-conceivable system with a plurality of LSIs illustrated in FIG. 1, but in contrast to the system in FIG. 1, the second embodiment in FIG. 6 does not need the system management device 2 for the chassis B. In addition, according to the second embodiment, only one system interface to perform various register settings of each LSI will suffice.

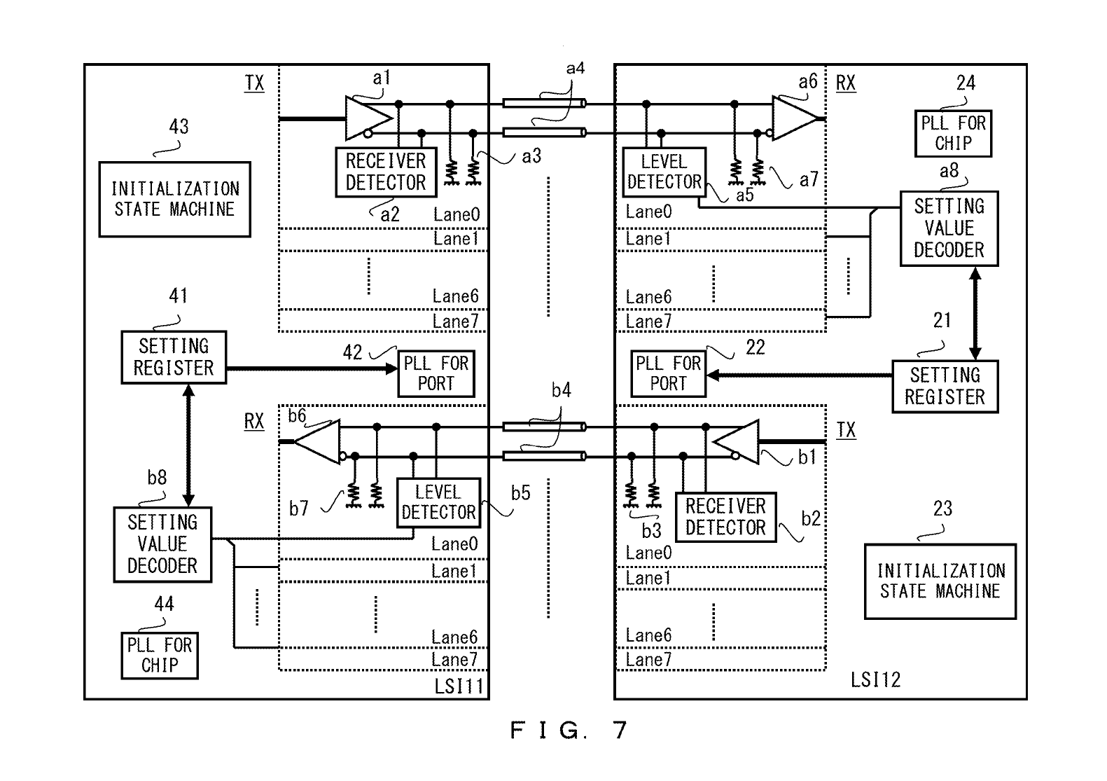

Next, FIG. 7 illustrates a facing lane configuration example in which only a portion of facing LSIs is extracted from the system with a plurality of LSIs of the second embodiment in FIG. 6. The LSI 11 and the LSI 12 are connected in a facing manner.

In FIG. 7, the upper half illustrates a path to transmit data from the LSI 11 to the LSI 12, and the lower half illustrates a path to transmit data from the LSI 12 to the LSI 11. At the time of normal operation, an exchange of data is performed between the LSI 11 and the LSI 12 using both the upper half and the lower half.

In FIG. 7, a1 and b1 illustrate a transmission buffer. In addition, a6 and b6 illustrate a receiving buffer. From the transmission buffer a1 of the LSI 11, two signal lines are connected to the receiving buffer a6 of the facing LSI 12 via a transmission path a4. In the same manner, also from the transmission buffer b1, two signal lines are connected to the receiving buffer b6 of the facing LSI 11 via a transmission path b4. An example in which the two signal lines use differential signal having high noise tolerance is illustrated. In order to prevent unnecessary noise and to improve transmission quality, on the transmission path a4 a termination resistor a3 is connected at the transmission buffer a1 side, and a termination resistor a7 is connected at the transmission buffer a6 side. For the same purpose, on the transmission path b4 a termination resistor b3 is connected to the transmission buffer b1 side, and a termination resistor b7 is connected at the receiving buffer b6 side. Furthermore, at the transmission buffer a1 side, a receiver detector a2 for detecting a facing lane is provided.

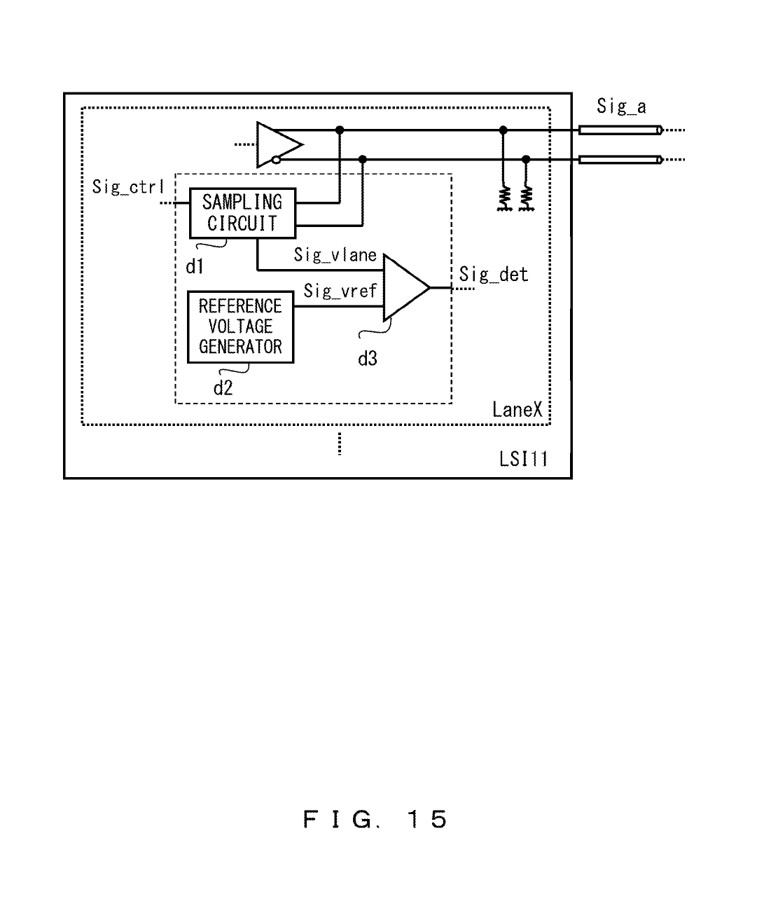

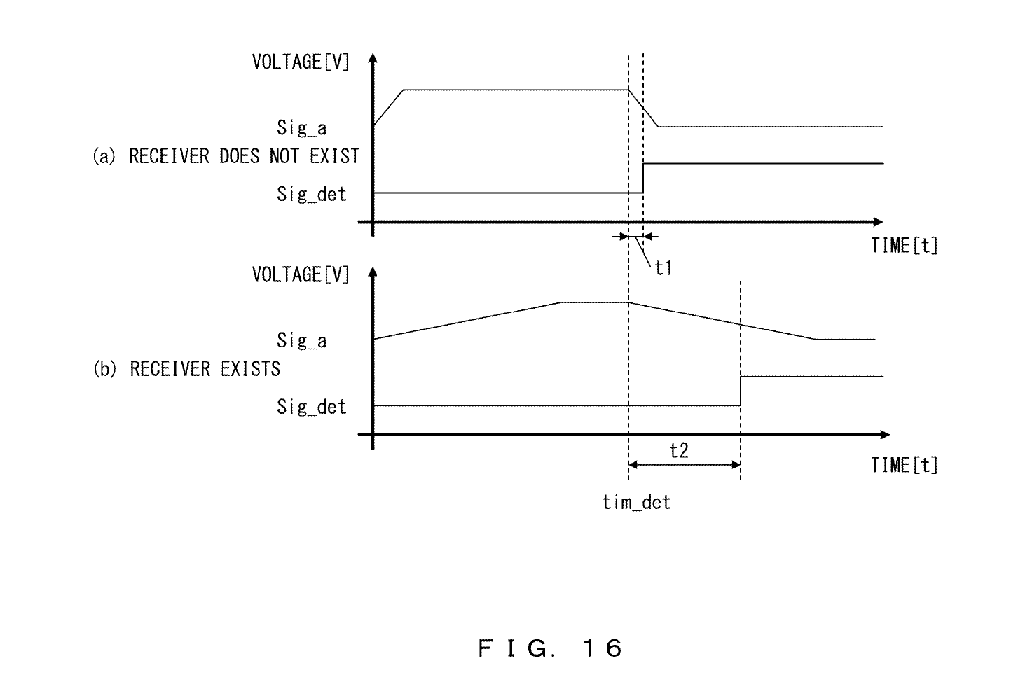

In the same manner, at the transmission buffer b1 side, a receiver detector b2 is provided. The receiver detector a2 is configured to be able to detect whether the facing LSI 12 (receiver) exists, from the condition of the lane of the transmission path a4. In the same manner, the receiver detector b2 is configured to be able to detect whether the facing LSI 11 exists, from the condition of the lane of the transmission path b4. The circuit configuration and the operation of the receiver detector are described later using FIG. 15 and FIG. 16.

On each lane of the transmission path a4 at the receiving buffer a6 side of the LSI 12, a level detector a5 for detecting the signal level on each lane of the transmission path a4 is connected. The level detector a5 of each lane is connected to a setting value decoder a8 for decoding the bit value of each lane of the initial setting code transmitted by the facing LSI 11. Then, the setting value decoder a8 is connected to a setting register 21 of the LSI 12. In the same manner, on each lane of the transmission path b4 of the receiving buffer b6 side of the LSI 11, a level detector b5 for detecting the signal level on each lane of the transmission path b4 is connected. The level detector b5 of each lane is connected to a setting value decoder b8 for decoding the bit value of each lane of the initial setting code transmitted by the facing LSI 12. Then, the setting value decoder b8 is connected to a setting register 41 of the LSI 11.

The setting register 41 in the LSI 11 and the setting register 21 in the LSI 12 respectively perform setting of each part in each LSI. For example, in the LSI 11, the setting register 41 is connected to a PLL for port 42. In the same manner, in the LSI 12, the setting register 21 is connected to a PLL for port 22.

Meanwhile, for the PLL which is used to control each operating frequency in the LSI 11 and the LSI 12, two types of PLLs for a port/chip are mounted. PLLs for chip 44 and 24 respectively oscillate a clock at a constant frequency, once the respective power of the LSI 11 and the LSI 12 is turned on. The PLL for port 42 in the LSI 11 starts, after receiving initial setting via the data lane b4, using the bit value. In the same manner, the PLL for port 22 starts, after receiving initial setting via the data lane a4, using the bit value. Meanwhile, the initial frequency setting for the PLL for port 42 in the LSI 11 receives initial setting via the setting register 41 from the system management device 1 in FIG. 6. In this case, it shows a case to be setting from the facing LSI.

The initialization state machine 43 in the LSI 11 and the initialization state machine 23 in the LSI 12 control the execution of a series of initialization sequences in each module of each LSI.

In the second embodiment, having the configuration described above, first, for the LSI 11, the initial register value is set in the setting register 41 from the system management device 1 in FIG. 6 to the setting register 41 in the LSI 11.

Next, in the chassis A in FIG. 6, from the LSI 11 to the LSI 12, a communication operation as follows is executed using each lane a4 of the data bus to send and receive normal data in the operating state. First, the receiver detector a2 provided for each lane detects whether or not the facing LSI 12 is connected to the lane, from the state of each lane a4. By the operation of the receiver detector a2 of each lane, which lane is available for use is judged. For example, when the number of lanes is eight, when all the lanes are available for use, all eight lanes are used. Meanwhile, when four or more and seven or fewer lanes are available, an arbitrary four available lanes are used. Using the lanes determined in this way, the initialization state machine 43 in LSI 11 executes a control operation as follows. That is, the signal level state of each lane a4 to be used is set to a state having a prescribed pattern in which the logic level “0” and the logic level “1” change in an alternate manner at a short first time interval a prescribed number of times (five times for example). After that, for the LSI 12 to recognize the initialization setting code, the signal level state of each lane a4 to be used is set to a state having a second time interval that is sufficiently longer than the first time interval, and in which each lane becomes the logic level “0” or “1” corresponding to each bit value “0” or “1” of the initial setting code.

In the facing LSI 12, for each lane a4, each level detector a5 detects the signal level of each lane. Then, based on each signal level detected at each lane, the setting value decoder a8 detects the state of the prescribed pattern described above, and after that, detects the state corresponding to each bit value of the subsequent initial setting code. By performing this detection operation for each lane, the setting value decoder a8 decodes the bit string of the initial setting code, and sets it in the setting register 21 in the LSI 12.

As described above, in the second embodiment, even in the state in which operating frequencies of the LSI 11 and the LSI 12 have not yet been synchronized, using each lane a4 of the data bus to send and receive normal data in the operating state, the LSI 11 and the LSI 12 may communicate and the initial setting code may be communicated so as to adjust to the operation frequencies of the LSI 11 and the LSI 12. The initial setting code set in the setting register 21 sets the operating frequency of the PLL for port 22. As a result, it becomes possible to synchronize the operating frequency of the PLL for port 22 in the LSI 12 with the operating frequency of the PLL for port 42 in the facing LSI 11.

Then, after synchronizing the respective operating frequencies of the PLL for port 42 and the PLL for port 22, the initialization state machine 43 in the LSI 11 executes the initialization sequence to communicate the normal packet command with the initialization state machine 23 in the LSI 12, using the respective lanes a4 and b4 of each data bus. Accordingly, it becomes possible to set other setting values for physical layer initialization from the LSI 11 for the facing LSI 12.

As described above, in the chassis A in FIG. 6, after the initialization process from the LSI 11 for the LSI 12 is completed, an initialization process from the LSI 12 for the LSI 14 is executed. When it is completed, further, an initialization process from the LSI 14 in the chassis A for the LSI 23 in the chassis B is executed. Further, when it is completed, in the chassis B, an initialization process from the LSI 23 for the LSI 21 and the LSI 24 is performed in the chassis B. As described above, by preparing only one system management device 1 and the system interface, it becomes possible to make initialization processes autonomously between the respective LSIs sequentially in a beaded linked manner.

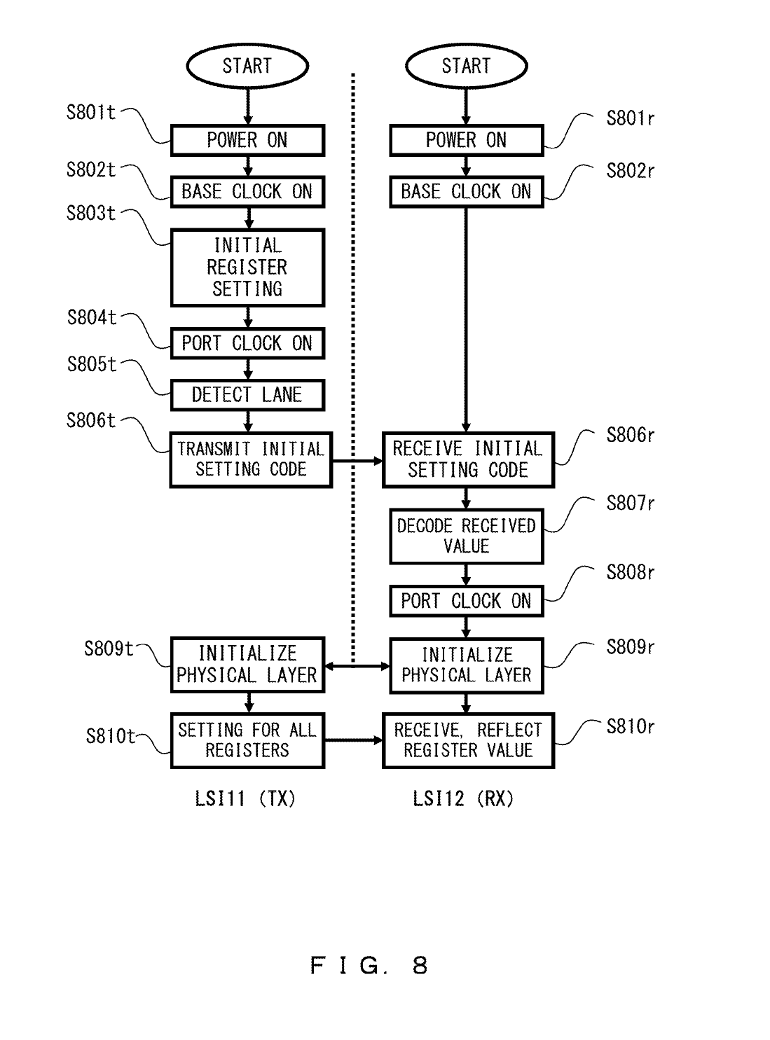

FIG. 8 is a flowchart of a setting process of a physical layer initial setting value in the second embodiment. In this flowchart, a process group S801t-S810t of the transmitting side port (TX port) is illustrated on the left side, and a process group S801r-S810r of the receiving side port (RX port) is illustrated on the right side. Here, as an example, the LSI 11 is the transmitting side, and the LSI 12 is the receiving side. That is, it is an example in which the upper half of FIG. 7 operates. The process group S801t-S810t of the transmitting side port (TX port) is processes for the initialization state machine 43 in the LSI 11 illustrated in FIG. 7 to execute a prescribed transmission control program. Meanwhile, the process group S801r-S810r of the receiving side port (RX port) is processes for the initialization state machine 23 in the LSI 12 illustrated in FIG. 7 to execute a prescribed receiving control program. When the LSI 12 is the transmitting side and the LSI 11 is the receiving side (the lower half of FIG. 7), the initialization state machine 23 in the LSI 12 executes a transmission control program corresponding to the process group S801t-S810t. Meanwhile, the initialization state machine 43 in the LSI 11 executes a receiving control program corresponding to the process group S801r-S810r.

In FIG. 8, first, in step S801t, the power of the LSI 11 is turned on. In the same manner, in step S801r, the power of the LSI 12 is turned on. Once the power is turned on, the LSI 11 and the LSI 12 autonomously turn on the base clock based on a reference block supplied from outside the chip (steps S802t and S802r). The base clock is assumed to be 1 MHz for the convenience of explanation. However, the present embodiment does not limit this base clock speed. The base clock is a clock that the PLLs 44 and 24 in FIG. 7 respectively output.

After the power-on operation above, in the present embodiment, in step S803t, the initial register value is set from the system management device 1 in FIG. 6 for the setting register 41 (FIG. 7) in the LSI 11.

After that, in step S804t, by the port clock set in the setting register 41 that depends on the data forwarding speed, the port clock for the physical layer is turned on.

Next, in step S805t, by each receiver detector a2 of each lane a4, the presence/absence of the facing lane is detected autonomously.

When a valid facing lane is detected, in step S806t, in the valid lane a4, with the transmission path being controlled so as to be a prescribed pattern described later, the initial setting code is transmitted.

Meanwhile, in the LSI 12 at the receiving side, the level detector a5 in FIG. 7 provided for each lane has started operation. For this reason, in step S806r, the signal level of the initial setting code transmitted from the LSI 11 side onto each valid lane is detected by each level detector a5 corresponding to each lane.

Each signal level detected at each level detector a5 is decoded respectively by the setting value decoder a8 in FIG. 7 in step S807r, and the decoding results of the valid lanes are put together, decoded as the initial setting code, and set in the setting register 21 in FIG. 7.

After that, in step S808r, at the frequency corresponding to the initial setting code set in the setting register 21, the port clock is turned on. Accordingly, the PLL for port 22 in the LSI 12 starts operation, and setting for physical layer initialization of each LSI is completed.

After that, in step S809t (transmitting side) and S809r (receiving side), using the respective lanes a4 and b4 of each data bus, by the initialization sequence, initialization of the physical layer is performed. Then, in step S810t, all the register values in the LSI 11 at the transmitting side to be transmitted to the LSI 12 are transmitted to the LSI 12, and in step S810r, receiving and setting of those register values are executed in the LSI 12 at the receiving side. Accordingly, both ports of the data bus move to the normal operating state in which transmission is available.

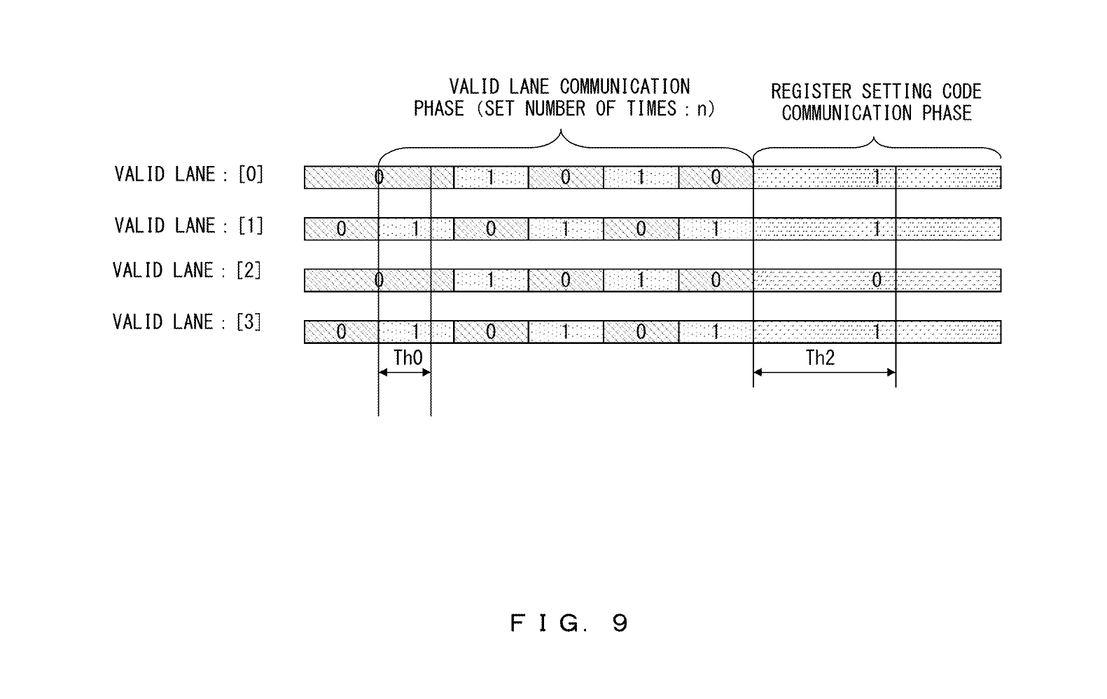

FIG. 9 is an explanatory diagram of the communication operation of the initial setting code performed in steps S806t and S806r in FIG. 8. FIG. 9 illustrates a state in which the LSI 11 at the transmitting side controls, in step S806t, the signal level on the valid lane a4 (FIG. 7) detected in step S805t. The LSI 11 at the transmitting side generates a prescribed pattern of 1->0 change for the number of times set in the setting registers 41 and 21 in FIG. 7 (valid lane communication phase in FIG. 9). After that, the bit value of the initial setting to be actually transmitted is sent. In the example in FIG. 9, the initial setting code is transmitted using four lanes of the valid lanes, and the respective bit values of the initial setting values are “1” for the valid lanes [0], [1], [3], and “0” for the valid lane [2]. As a result, the four-bit value “1101” of the initial setting code is transmitted.

Meanwhile, the setting value decoder a8 of the LSI 12 at the receiving side detects the state of the lane described above. First, the LSI 12 operates to detect the prescribed pattern of a 0->1 change at all the lanes. As illustrated in FIG. 9, regarding the pattern that is equal to or above threshold Th0 and equal to or below threshold Th2 in regard to the time length, a judgment is made that the state of the lane has become “0” or “1”. That is, when it is equal to or below Th0, it is determined that the lane changed temporarily due to noise and the like, and when it is equal to or below Th2, it is determined that the value is different from the initial setting code. Then, when “0” or “1” is detected, next, expecting the opposite value, the LSI 12 waits for a change of the data lane again. Then, a lane in which “1” or “0” of Th0 or above and Th2 or below is detected n=5 times or more is determined as a valid lane, and each bit value subsequent to the prescribed pattern is expected at the same time. Regarding a lane in which “0” or “1” is detected five times or more, when data having a time length of equal to or more than Th2 is received, the value is judged as the bit value of the initial setting code, and is set in the setting register 21. Meanwhile, when receiving is expected with a signal change of five times, as illustrated in the valid lanes [0] and [2] in FIG. 9, the first “0” change is not detected at the receiving side, and the transmitting LSI 12 transmits the prescribed pattern of “0” and “1” change six times or more. The initial setting code may be received according to the control as described above.

The expected time: (Th0<Th2) is measured using a base clock for which the frequency is 1 MHz for example. It is set for example as Th0=3 [uS] (three cycles), Th2=10 [uS] (ten cycles). However, when these lane states are satisfied by the mechanism of the receiver detectors a2 and b2, there is a risk of receiving a wrong initial setting code. For this reason, as the Th0, Th2, for the number of times n for a prescribed pattern of receiving “0”, “1”, an appropriate number of times according to the system needs to be set. In the present embodiment, since the number of detections of the prescribed pattern of receiving “0” and “1” is set as five times and Th2 has a sufficiently long pattern that does not appear in the receiver detectors a2 and b2, the initial setting code may be received correctly.

In the present embodiment, since there is no opportunity to change the values of the setting values of Th0, Th1 and n of the LSI 12 from outside, a sufficient examination at the time of designing is needed. In particular, it is desirable to set a long time that will never appear except when representing the initial setting code for Th2.

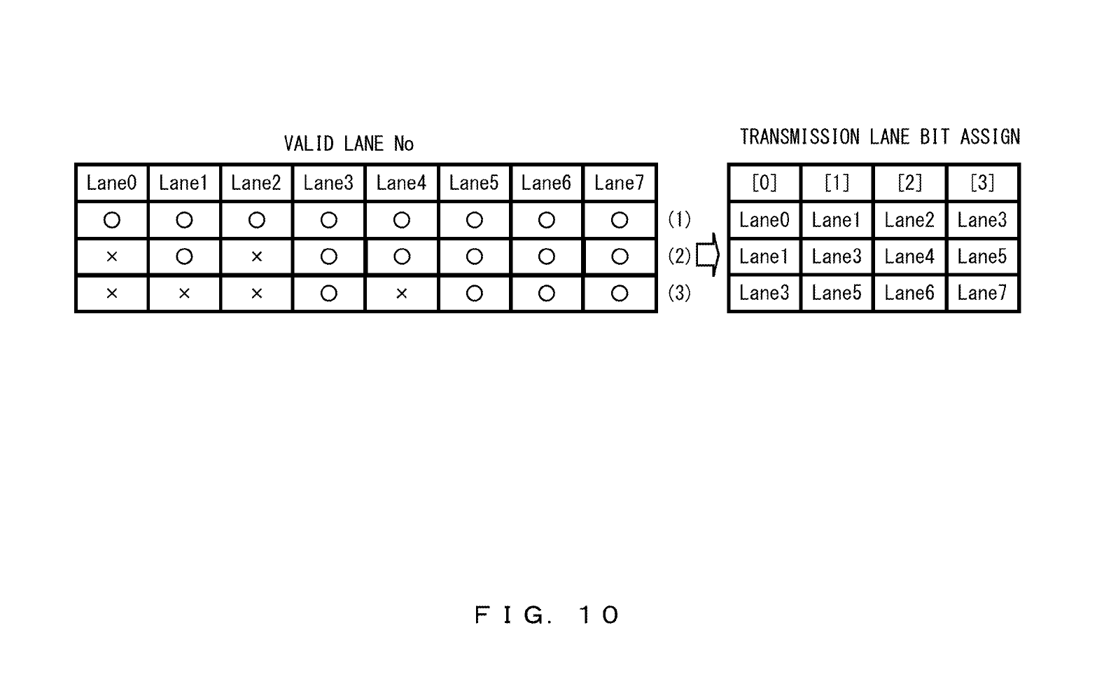

FIG. 10 is a diagram illustrating an example of an initial setting code transmission lane in the second embodiment, and illustrates an example of a bit assign of the valid lane representing which lane is used to transmit the initial setting code. There is a case in which each lane is not active. In an undetected lane at the receiver detectors a2 and b2 in FIG. 7, data cannot be transmitted, and the initial setting code is transmitted only in a lane that is detected as active lane.

For example, as illustrated as the 0 mark from Lane0 (the 0th lane) to Lane7 (the 7th lane) in FIG. 10 (1), when the facing receiver is valid in all lanes, the initial setting code is transmitted using lanes Lane0/Lane1/Lane2/Lane3. Meanwhile, as illustrated as the x mark in lanes Lane0 and Lane2 in FIG. 10(2), when the 0th and second lanes are not active, the setting code is transmitted using lanes Lane1/Lane3/Lane4/Lane5. Furthermore, as illustrated as the x mark in Lane0, 1, 2, 4, the setting code is transmitted using lanes Lane3/Lane5/Lane6/Lane7. As described above, the initial setting code is transmitted using four bits from the lower number of the valid lanes.

In this embodiment, it is assumed that up to four lanes are out of order, the data bus degenerated, and the operation continued by using active four lanes. In a case of four lanes or more being out of order, the data bus becomes unavailable for use in the first place, and therefore the specification is made so that the initial setting code is transmitted in four lanes.

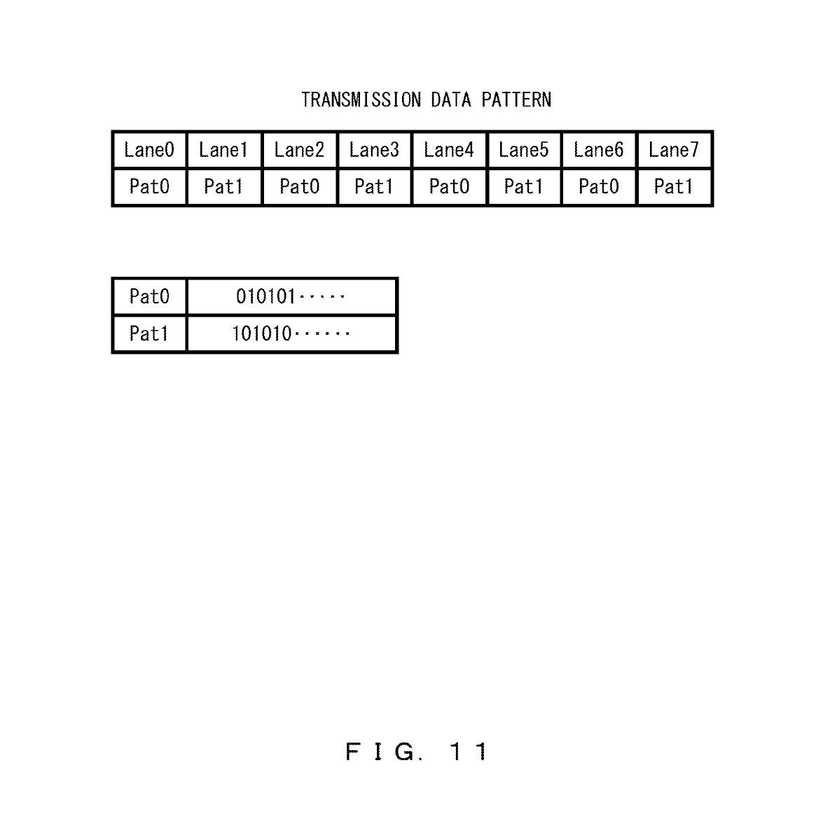

FIG. 11 is a diagram illustrating an example of a transmission prior notice pattern being the prescribed pattern transmitted in each lane before the transmission of the bit value of the initial setting code from the LSI 11 at the transmitting side, and illustrates an example of a case with a “0” “1” change pattern. In the present embodiment, an example of reversing the “0” “1” transmission pattern in physically adjacent lanes is illustrated. With such a transmission, there is a possibility that shortness in the lanes and the like may also be detected, and for the LSI 12 at the receiving side, a checker to check that the prescribed pattern represented by Pat0 and the prescribed pattern represented by Pat1 in FIG. 11 are received in adjacent lanes may be provided.

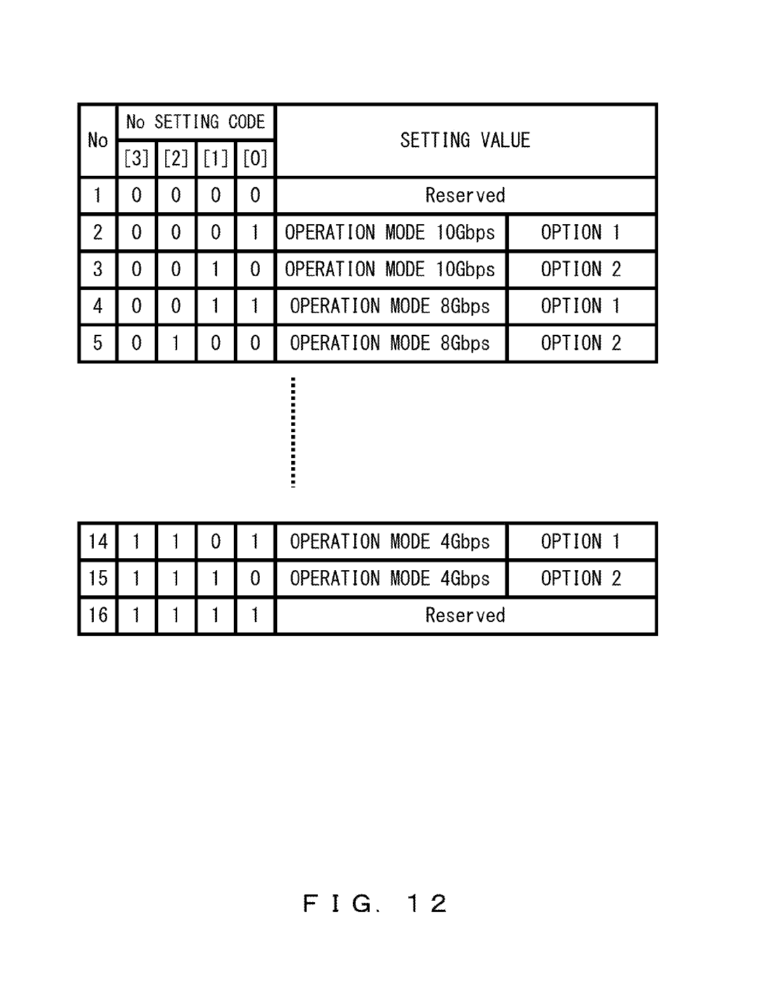

FIG. 12 is a diagram illustrating an example of a setting content of the initial setting code in the second embodiment. Since it is desirable that “0” “1” be different in at least one bit so as not to detect a short situation of the signal level when the lane is out of order, the setting values “0000” and “1111” of the initial setting code are backup codes. The remaining 14 kinds of initial setting codes other than the above two may be set. For example, when the setting value is “0001”, the setting of the transmission speed 10 Gbps is set to the frequency of the port clock, and an option 1 to become the analog setting for oscillating the port clock is set. The value set by the initial setting code is a minimum content that has to be determined by the time of initialization, and for many other setting values, the setting may be made for the purposes of normal operation from the physical layer via the data bus, as a packet command of register write.

With such a setting, the LSI 11 is able to perform the setting of the port clock of the facing LSI 12, perform physical layer initialization at the same clock frequency, and to start at the same transmission speed together. Then, after this start, setting for all the registers of the LSI 12 is performed via the transmission path started earlier. By repeating this method, in the configuration example of the system with a plurality of LSIs illustrated in FIG. 6, it becomes possible to perform setting from one system management device 1 for all physically connected LSIs.

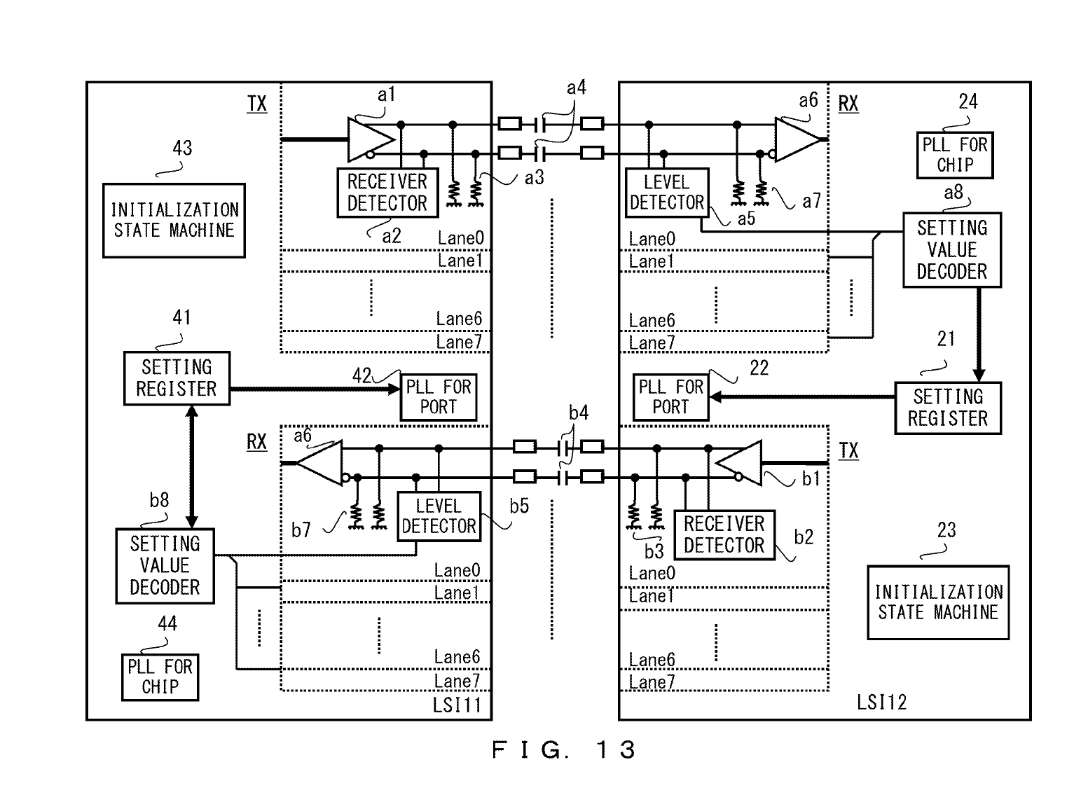

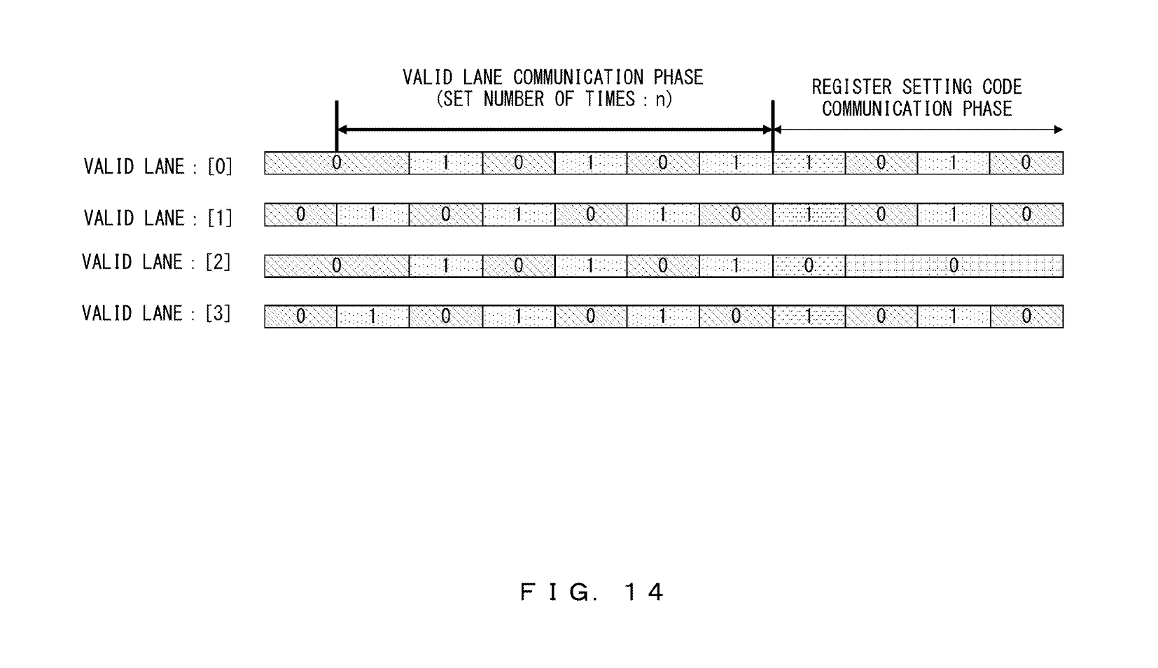

FIG. 13 is a diagram illustrating a facing lane configuration, which is the third embodiment, which is different from the second embodiment illustrated in FIG. 7. In FIG. 13, the parts to which the same numbers as in the configuration in FIG. 7 are assigned perform the same operation as in the case of FIG. 7. The third embodiment in FIG. 13 differs from the second embodiment in FIG. 7 in that an AC (alternating current) coupling capacitor is inserted on each lane a4 and b4 on the transmission path connecting the LSI 11 and the LSI 12. In a high-speed transmission, to improve how noise tolerance it is, AC connection is performed in some cases. In this case, a different operation from the case in the second embodiment needs to be performed. The basic operations in the third embodiment are the same as in the second embodiment. However, the communication operation of the initial setting code explained using FIG. 9 is unavailable. When there is an AC connection, even when “0” or “1” is changed for a long time (in a DC-like manner) as illustrated in FIG. 9, the receiving side is unable to detect the change. Therefore, an initial setting code communication operation as illustrated in FIG. 14 is used.

In FIG. 14, first, the LSI 12 receives the prescribed pattern of the repetition of “0” “1” transmitted in the valid lane. The set number of times (n) of toggles, in this case, that is the prescribed receiving pattern starting from “1”, is detected. For example, when “1”->“0”->“1”->“0”->“1” is received, the bit value of the initial setting code is recorded from the next one.

At this time, it is assumed that the bit value “1” of the initial setting code is received in a lane repeating a “1”->“0” change, and the bit value “0” of the initial setting code is received at a lane fixed at “0”. That is, the valid lanes [0] [1] [3] in FIG. 14 make a judgment that “1” was received, and the valid lane [2] makes a judgment that “0” was received. However, the clock sampled at the receiving side needs to be small with respect to the transmission pattern so that the transmission data may be sampled without fail. For example, the structure may be made so that the transmitted data pattern has a minimum frequency that makes it possible to transmit it, and the operating speed of the receiver detector at the receiving side is about three times that so as to secure data.

FIG. 15 illustrates a structure example of the receiver detectors a2 and b2 in FIG. 7 (second embodiment) or FIG. 13 (third embodiment). In FIG. 15, Sig_a, which is a signal line corresponding to the lane a4 or b4 between the LSI 11 and the LSI 12 in FIG. 7 or FIG. 13, is connected to a sampling circuit d1 separately from the transmission driver a1 or b1 in FIG. 7 or FIG. 13. The sampling circuit d1 has a voltage control function to forcibly turn the Sig_a voltage into “H”, and a voltage level detection function to detect the voltage level of Sig_a. The voltage Sig_vlane of Sig_a detected by the sampling circuit d1 is compared by a voltage level comparator (Cmp in the drawing) d3 with a reference voltage Sig_vref generated by a reference voltage generator d2. Then, when the Sig_vlane of Sig_a is equal to or below the reference voltage Sig_vref, the output voltage Sig_det of the voltage level comparator d3 becomes “H”.

FIG. 16 illustrates an operating waveform example in the receiver detector a2 or b2 in FIG. 7 or FIG. 13 having the example in FIG. 15. Sig_a is the lane voltage, and Sig_det represents the output signal of the receiver detector a2 or b2. The vertical axis represents the voltage [V], and the horizontal axis represents the time [t].

The explanation is made according to the order of control. Sig_a is turned to “H” by the voltage control function of the sampling circuit d1 (FIG. 15) first. After that, after a wait for a certain time, the level detection function of the sampling circuit d1 is activated at the timing of tim_det in the drawing. At this time, the voltage of Sig_a steps downdue to the termination resistor in the LSI. When it steps down to a voltage of a certain amount, Sig_det turns to “H”.

FIG. 16(a) illustrates a case in which the LSI at the receiver side does not exist, and FIG. 16(b) illustrates a case in which the LSI at the receiver side exist. When the receiver does not exist, the capacity existing in the entirety of Sig_a is small, and the time t1 in which Sig_det becomes “L”->“H” is short. On the other hand, when the receiver exists, the capacity in the entirety of Sig_a is large, and the time t2 in which Sig_det becomes “L”->“H” is longer. Whether or not a facing receiver exists may be judged by the difference in the times t1 and t2.

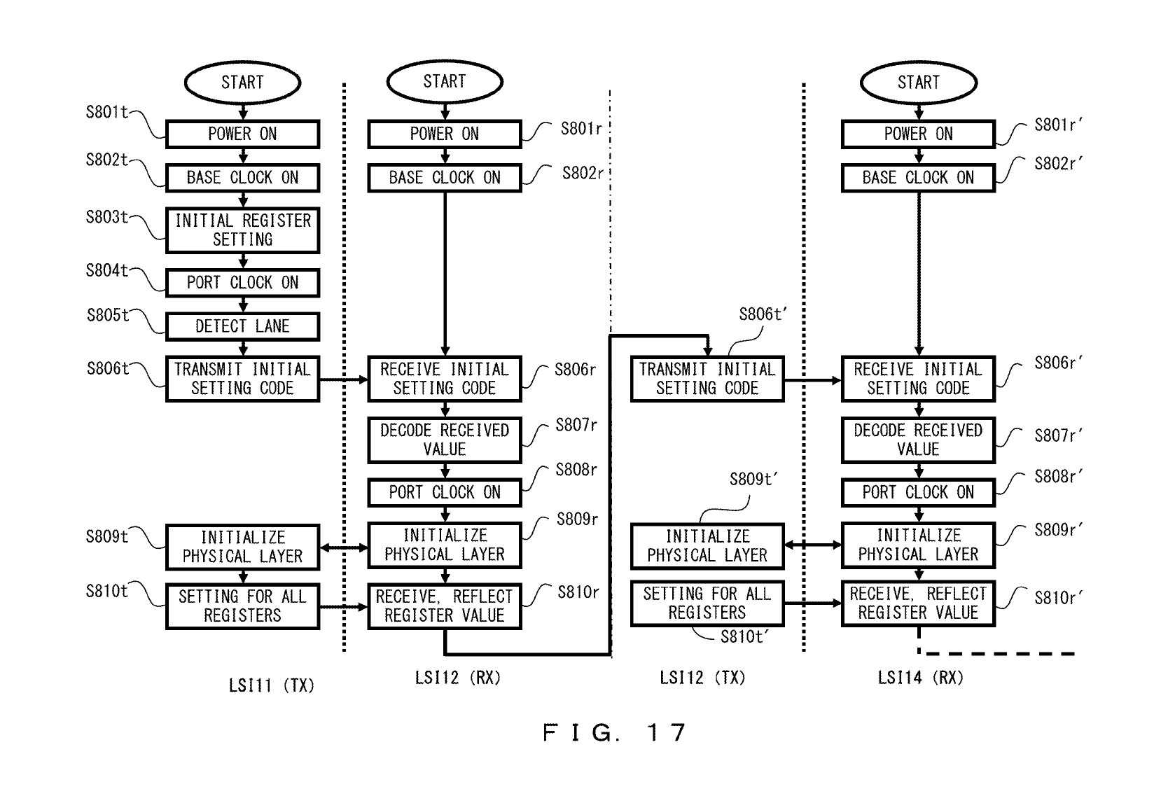

FIG. 17 is a flowchart expanding the flowchart of the setting process of the physical layer initial setting value in the second embodiment illustrated FIG. 8. In FIG. 17, the processes with the same step numbers as those of FIG. 8 are the same processes as those of FIG. 8. While the physical layer initialization flow of two LSIs is illustrated in the example of FIG. 8, FIG. 17 illustrates a physical layer initialization flow of three LSIs. Meanwhile, while there are three LSIs in this case, in a system with three or more LSIs, the same operation for the second LSI may be performed for the subsequent LSIs (third LSI and subsequent ones).

In FIG. 8, the initial setting value is communicated from the LSI 11 to the LSI 12. The part is the same as in the flowchart in FIG. 17. In the description below, the operation after that is explained.

The LSI 12, after the physical layer initialization with the LSI 11 is completed, performs initialization of the physical layer with the LSI 14, for example. The series of operations are almost equivalent to the case of the LSI 11 and the LSI 12. An explanation is made in order below.

The LSI 12 communicates the initial setting code to be received at the receiving port (RX) side to its own transmission port (TX) side connected to the LSI 14 (step S806t′). The communicated initialization information is transmitted to the LSI 14.

The LSI 14 starts autonomously after the power on operation in the same manner as the steps S801r, S802r in FIG. 8 (steps S801r′, S802r′). After that, in the same manner as step S806r in FIG. 8, the LSI 14 waits for transmission of the initial setting code (step S806′).

The LSI 14 that received the initialization code executes a series of physical layer initialization sequences in the same manner as steps S807r-S810r in FIG. 8 (steps S807r′-S810r′). In steps S809t′ (transmitting side) and S809r′ (receiving side), using each lane of each data bus, initialization of the physical layer is performed by the initialization sequence. Then, in step S810t′, all register values to be transmitted to the LSI 14 in the LSI 12 at the transmitting side are transmitted to the LSI 14, and in the S810r′, in the LSI at the receiving side, in the process of receiving, setting of those register values is performed. As a result, both ports of the LSI 12 and the LSI 14 move to the normal operation state in which transmission is available.

After that, when initialization of a port with another LSI is desired, the initial setting code is transmitted to the port. After that, the same procedure as has been carried out so far may be repeated.

This sequence is not limited to the above description. In addition, the order of initialization may also be controlled by the user as needed.

According to the first, second, third embodiments described above, it becomes possible to reliably perform setting for registers necessary for the initialization of a facing LSI.

According to the first through third embodiments, since the setting of initialization may be performed sequentially from one device, as long as the respective devices are connected physically, it becomes possible to start (initialize) all devices of the system.

According to the first, second, and third embodiments, since an access to only one device will do, a centralized management becomes available even for large-scale connections.

According to the first, second, third embodiments, there is a possibility to reduce signal lines from the system management device. At least in the initialization of each LSI, the system management device is only required to be connected to one device.

According to the first, second, and third embodiments, by making a certain circuit operate with a clock of a fixed clock without fail, and by setting the initial setting value in the setting register by the circuit using the fixed clock, the LSI receiving the initial setting code is able to start the physical layer at various operating frequencies.

According to the first, second, and third embodiments, since the initial setting value may be set in the setting register with a very simple circuit compared with the method to perform register setting after initializing the data bus, the difficulty of the circuit design is low and the designing is easy.

After performing setting of initialization from outside for one semiconductor integrated circuit, even when the semiconductor integrated circuits are not synchronized with each other, it becomes possible to set the initial setting code to enable starting the physical layers of the semiconductor integrated circuit in synchronization with each other using the transmission path to exchange normal data in the operating state. Accordingly, by accessing one semiconductor integrated circuit, it becomes possible to perform initialization of a plurality of semiconductor integrated circuits in a simple procedure while reducing the circuit scale.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An autonomous initialization method of a facing port of an integrated semiconductor circuit, the autonomous initialization method comprising:
turning each lane after turning to a first signal state for detecting a valid lane to a second signal state corresponding to each bit of initial setting code, on a transmission path connecting a first semiconductor integrated circuit that is started by a system management apparatus and a second semiconductor integrated circuit that is not started by the system management apparatus, when connection of the first semiconductor integrated circuit to the second semiconductor integrated circuit is detected;
detecting a signal state for each lane of the transmission path in the second semiconductor integrated circuit;
decoding each bit value of the initial setting code in the second semiconductor integrated circuit, for each lane of the transmission path, based on the detected signal state, when the second signal state is detected after detecting the first signal state; and
executing an initialization process of a facing port to which the transmission path is connected, based on the decoded initial setting code, by the first semiconductor integrated circuit and the second semiconductor integrated circuit.

2. The autonomous initialization method of a facing port of an integrated semiconductor circuit according to claim 1, wherein
the first signal state is a state having a prescribed pattern in which a logic level of a signal of each lane on the transmission path changes in an alternate manner at a first time interval a predetermined number of times; and
the second signal state is a state having a second time interval that is longer than the first time interval, and in which each of the lanes becomes a logic level corresponding to each bit value of an initial setting code.

3. The autonomous initialization method of a facing port of an integrated semiconductor circuit according to claim 1, wherein
the first signal state is a state having a prescribed pattern in which a logic level of a signal of each lane on the transmission path changes in an alternate manner at a first time interval a predetermined number of times; and
the second signal state is a state which is either a state in which the logic level changes in an alternate manner according to each bit value of the initialization code or a state in which the logic level is fixed.

4. The autonomous initialization method of a facing port of an integrated semiconductor circuit according to claim 1, wherein:
initial setting in a physical layer is performed by
turning on a base clock of the first semiconductor integrated circuit;
detecting an existence of a facing lane;
setting information to determine a valid lane in a register in the initial setting unit;
turning on the port clock;
sending information to determine the valid lane to the second semiconductor integrated circuit;
determining the valid lane;
transmitting the initial setting code corresponding to a port clock to the second semiconductor integrated circuit via the valid lane;
receiving, at the second semiconductor integrated circuit, the initial setting code from the first semiconductor integrated circuit;
decoding the initial setting code;
turning on a port clock of the second semiconductor circuit corresponding to a port clock of the first semiconductor circuit by the initial setting code; and
performing transmitting/receiving by the same port clock by the first semiconductor integrated circuit and the second semiconductor integrated circuit.

5. The autonomous initialization method of a facing port of an integrated semiconductor circuit according to claim 1, the autonomous initialization method further comprising:
setting the second semiconductor integrated circuit in which the initialization process ended as a new first semiconductor integrated circuit;
setting another semiconductor integrated circuit connected to the new first semiconductor circuit as a new second semiconductor integrated circuit; and
performing the turning, the detecting, the decoding, and the executing between the new first semiconductor integrated circuit and the new second semiconductor integrated circuit.

6. A semiconductor integrated circuit comprising:
a transmission data lane control unit configured to, on a transmission path to be connected to another semiconductor integrated circuit, when connection of the other semiconductor integrated circuit is detected, after turning to a first signal state for detecting a valid lane, turn each lane on the transmission path to a second signal state corresponding to each bit value of an initial setting code;
a level detector configured to detect a signal state for each lane of the transmission path, for a signal received from the other semiconductor integrated circuit;
an initial setting unit configured to decode each bit value of the initial setting code and to perform initial setting, based on the second signal state detected by the level detector, for each lane of the transmission path.

7. The semiconductor integrated circuit according to claim 6, wherein
the transmission data lane control unit makes the first signal state of each lane on the transmission path have a prescribed pattern in which a logic level changes in an alternate manner at a first time interval a prescribed number of times, and after that, controls the second signal state to have a second time interval that is longer than the first time interval and each of the lanes to be a logic level corresponding to each bit value of the initial setting code.

8. The semiconductor integrated circuit according to claim 6, wherein
the transmission data lane control unit makes the first signal state of each lane on the transmission path have a prescribed pattern in which a logic level changes in an alternate manner at a first time interval a prescribed number of times, and after that, controls the second signal state to be a state in which the logic level changes in an alternate manner according to each bit value of the initial setting code or a state in which the logic level is fixed.

9. The semiconductor integrated circuit according to claim 6, wherein
initial setting in a physical layer is performed by
turning on abase clock of the semiconductor integrated circuit;
setting information to determine a valid lane in a register in the initial setting unit;
turning on a port clock;
sending information to determine the valid lane to the other semiconductor integrated circuit;
determining the valid lane;
transmitting the initial setting code corresponding to the port clock to the other semiconductor integrated circuit via the valid lane;
receiving, at the other semiconductor integrated circuit, the initial setting code from the first semiconductor integrated circuit;
decoding the initial setting code;
turning on the port clock of the other semiconductor circuit corresponding to the port clock of the semiconductor circuit by the initial setting code; and
performing transmitting/receiving by a same port clock via the semiconductor integrated circuit and the other semiconductor integrated circuit.

10. The semiconductor integrated circuit according to claim 6, wherein
in the semiconductor integrated circuit which uses a system interface connected outside the semiconductor integrated circuit, the initial setting code is set from outside the semiconductor integrated circuit.
